(19) United States
(12) Patent Application Publication
(10) Pub. No.: US 2024/0047269 A1
(43) Pub. Date: Feb. 8, 2024

(54) MOLYBDENUM DEPOSITION IN FEATURES

(71) Applicant: Lam Research Corporation, Fremont, CA (US)

(72) Inventors: Jeong-Seok NA, San Jose, CA (US); Shruti Vivek THOMBARE, Sunnyvale, CA (US); Yao-Tsung HSIEH, San Jose, CA (US); David Joseph MANDIA, Fremont, CA (US); Chiukin Steven LAI, Sunnyvale, CA (US)

(21) Appl. No.: 18/258,973

(22) PCT Filed: Jan. 3, 2022
(86) PCT No.: PCT/US2022/011053

§ 371 Date: Jun. 22, 2023

Related U.S. Application Data
(60) Provisional application No. 63/199,525, filed on Jan. 5, 2021.

(51) Int. Cl. H01L 21/768; H01L 21/02; H01L 23/522; H01L 23/532; H01L 21/285

(52) U.S. Cl. CPC H01L 21/76877; H01L 21/02068; H01L 21/76865; H01L 21/76879; H01L 23/5226; H01L 23/53266; H01L 21/76843; H01L 21/28568

(57) ABSTRACT

Provided are deposition processes including deposition of a thin, protective Mo layer using a molybdenum chloride (MoClₓ) precursor. This may be followed by Mo deposition to fill the feature using a molybdenum oxyhalide (MoO_{y}X_{z}) precursor. The protective Mo layer enables Mo fill using an MoO_{y}X_{z} precursor without oxidation of the underlying surfaces. Also provided are in-situ clean processes in which a MoClₓ precursor is used to remove oxidation from underlying surfaces prior to deposition. Subsequent deposition using the MoClₓ precursor may deposit an initial layer and/or fill a feature.

### INCORPORATION BY REFERENCE

A PCT Request Form is filed concurrently with this specification as part of the present application. Each application that the present application claim benefit of or priority to as identified in the concurrently filed PCT Request Form is incorporated by reference herein in its entirety and for all purposes.

### BACKGROUND

In semiconductor fabrication, features such as lines and vias may be filled with conductive materials such as tungsten (W), copper (Cu) and cobalt (Co). As semiconductor devices scale down to 10 nm node and lower, line and via contact resistance increase rapidly in metal interconnects. This is due to the reduction in current-carrying cross-section, increase in electron scattering, and the increasing challenges of filling narrow features with current Cu or W process schemes in narrow features.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided are deposition processes including deposition of a thin, protective Mo layer using a molybdenum chloride (MoClₓ) precursor. This may be followed by Mo deposition to fill the feature using a molybdenum oxyhalide (MoO_{y}X_{z}) precursor. The protective Mo layer enables Mo fill using an MoO_{y}X_{z} precursor without oxidation of the underlying surfaces. Also provided are in-situ clean processes in which a MoClₓ precursor is used to remove oxidation from underlying surfaces prior to deposition. Subsequent deposition using the MoClₓ precursor may deposit an initial layer and/or fill a feature.

One aspect of the disclosure relates to a method including: providing a substrate including a feature having a feature bottom and feature sidewalls; depositing an initial molybdenum film in the feature using a molybdenum halide precursor and a reducing agent; and after depositing the initial molybdenum film, at least partially filling the feature with molybdenum using a molybdenum oxyhalide precursor.

In some embodiments, the feature bottom includes an oxidized metal silicide surface and the feature sidewalls includes oxidized metal surfaces, and the method further includes removing oxide from at least the oxidized metal silicide surface of the feature bottom to leave a metal silicide surface such that the initial molybdenum film is deposited directly on the metal silicide surface.

In some such embodiments, the metal silicide surface is one of: titanium silicide (TiSiₓ), nickel silicide (NiSiₓ), molybdenum silicide (MoSiₓ), cobalt silicide (CoSiₓ), platinum silicide (PtSiₓ), ruthenium silicide (RuSiₓ), and nickel platinum silicide (NiPt_{y}Siₓ).

In some embodiments, removing oxide from the oxidized metal silicide surface of the feature bottom includes a clean with a Cl-based plasma, HF vapor clean, or an ammonium fluoride clean.

In some embodiments, the feature bottom includes an oxidized semiconductor surface.

In some such embodiments, the semiconductor surface is silicon (Si).

In some such embodiments, the semiconductor surface is silicon-germanium (SiGe).

In some such embodiments, removing oxide from the oxidized semiconductor surface of the feature bottom includes a clean with a Cl-based plasma, HF vapor clean, or an ammonium fluoride clean.

In some embodiments, the initial molybdenum film is no more than five nanometers thick.

In some embodiments, the initial molybdenum film is no more than two nanometers thick.

In some embodiments, the molybdenum halide precursor is a molybdenum chloride precursor.

In some embodiments, the molybdenum halide precursor is molybdenum pentachloride (MoCl₅).

In some embodiments, the molybdenum halide precursor is molybdenum hexachloride (MoCl₆).

In some embodiments, the initial molybdenum film is deposited at a substrate temperature that is at least 300° C. and no more than 500° C.

In some embodiments, the initial molybdenum film is deposited at a substrate temperature that is at least 350° C. and no more than 450° C.

In some embodiments, the initial molybdenum film is deposited in a chamber, the chamber having a pressure of at least 30 Torr.

In some embodiments, the molybdenum oxyhalide precursor is a molybdenum oxychloride (MoOₓCl_{y}).

In some embodiments, the molybdenum oxyhalide precursor is a molybdenum oxyfluoride (MoOₓF_{y}).

In some embodiments, depositing the initial molybdenum film is performed in a first station of a multi-station chamber and depositing at least partially filling the feature is performed in at least a second station of the multi-station chamber.

Another aspect of the disclosure relates to a method including: providing a substrate including a feature having a feature bottom and feature sidewalls, where the feature bottom includes an oxidized surface; soaking the feature in a molybdenum halide precursor to remove oxide from the oxidized surface to leave an unoxidized surface; and depositing molybdenum into the feature, including directly on the unoxidized surface, using the molybdenum halide precursor and a reducing agent.

In some embodiments, depositing molybdenum into the feature includes depositing a non-selective molybdenum layer in the feature.

In some embodiments, depositing molybdenum into the feature includes selectively depositing a molybdenum layer on the unoxidized surface relative to the feature sidewalls.

In some such embodiments, further including, after depositing the molybdenum into the feature depositing a bulk molybdenum layer in the feature using a molybdenum oxyhalide precursor.

In some embodiments, the feature bottom includes a metal-containing surface, the feature sidewalls include a dielectric surface, and depositing molybdenum further includes selectively depositing molybdenum on the metal-containing surface relative to the dielectric surface.

In some embodiments, depositing molybdenum into the feature includes depositing a bulk molybdenum layer in the feature using the molybdenum halide precursor.

In some embodiments, the oxidized surface is an oxidized titanium nitride surface.

In some embodiments, soaking the feature in the molybdenum halide precursor is performed in a first chamber and depositing molybdenum into the feature is performed in a second chamber, where the first chamber and the second chamber are different chambers.

In some embodiments, soaking the feature in the molybdenum halide precursor and depositing the molybdenum into the feature are performed in the same chamber. In some such embodiments, the chamber is a multi-station chamber, soaking of the feature in the molybdenum halide precursor is performed in a first station of the multi-station chamber and depositing molybdenum into the feature is performed in at least a second station of the multi-station chamber.

In some embodiments, soaking the feature in the molybdenum halide precursor lasts at least 10 seconds in duration.

In some embodiments, soaking the feature in the molybdenum halide precursor lasts at least 60 seconds in duration.

In some embodiments, the molybdenum layer is no more than five nanometers thick.

In some embodiments, the molybdenum layer is no more than two nanometers thick.

In some embodiments, the molybdenum halide precursor is a molybdenum chloride precursor.

In some embodiments, depositing molybdenum into the feature is deposited at a substrate temperature that is at least 300° C. and no more than 500° C.

In some embodiments, where depositing molybdenum into the feature is deposited at a substrate temperature that is at least 350° C. and no more than 450° C.

In some embodiments, depositing molybdenum into the feature is deposited in a chamber, the chamber having a pressure of at least 10 Torr.

In some embodiments, depositing molybdenum into the feature is deposited in a chamber, the chamber having a pressure of at least 30 Torr.

In some embodiments, the method further includes, prior to soaking the feature, exposing the feature to an oxygen-containing chemistry to form the oxidized surface.

In some embodiments, the molybdenum chloride precursor is molybdenum pentachloride (MoCl₅) or molybdenum hexachloride (MoCl₆).

In some such embodiments, the oxidized surface is oxidized silicon, the molybdenum chloride precursor is molybdenum pentachloride, and soaking the feature in the molybdenum halide precursor removes oxide from the oxidized silicon, leaving silicon.

In some such embodiments, the oxidized surface is oxidized silicon germanium, the molybdenum chloride precursor is molybdenum pentachloride, and soaking the feature in a molybdenum halide precursor removes oxide from the silicon germanium, leaving silicon germanium.

In some such embodiments, the feature has a titanium nitride layer, the molybdenum chloride precursor is molybdenum pentachloride, and soaking the feature in a molybdenum halide precursor etches the titanium nitride layer.

In some such embodiments, the etch of the titanium nitride layer can be controlled to leave the titanium nitride layer at a desired thickness.

In some such embodiments, the titanium nitride layer is completely removed.

In some embodiments, soaking of the feature in the molybdenum halide precursor and depositing the molybdenum into the feature is performed in a first station of a multi-station chamber and further including depositing a bulk molybdenum layer into the feature, where the depositing the bulk molybdenum layer is performed in at least a second station of the multi-station chamber.

In some embodiments, soaking the feature includes continuously exposing the feature to the molybdenum halide precursor.

In some embodiments, soaking the feature includes exposing the feature alternating doses of the molybdenum halide precursor and an inert gas.

Another aspect of the disclosure relates to a method including: providing a substrate with a feature having a feature bottom and feature sidewalls; wherein the feature bottom has a metal nitride surface; depositing an initial molybdenum film on the feature sidewalls and the metal nitride surface of the feature bottom using a molybdenum halide precursor and a reducing agent; removing molybdenum film from the feature sidewalls, leaving a molybdenum film on the metal nitride surface feature bottom; and at least partially filling the feature with molybdenum.

In some embodiments, the metal nitride is titanium nitride (TiN).

In some embodiments, the metal nitride is a titanium silicide nitride (TiSiN).

In some embodiments, the metal nitride of the feature bottom overlies a stack having a semiconductor surface and a titanium silicide (TiSi) layer.

In some embodiments, the semiconductor surface is silicon (Si).

In some embodiments, the semiconductor surface is silicon-germanium (SiGe).

In some embodiments, the method further includes removing at least some metal nitride from the feature sidewalls before depositing an initial molybdenum film on the sidewalls and the metal nitride surface of the feature bottom.

These and other aspects are discussed further below with reference to the drawings.

### BRIEF DESCRIPTION OF DRAWINGS

FIGS. 1 and 2 are flow diagrams showing certain operations in methods according to various embodiments.

FIGS. 3A-5D are schematic diagrams showing cross-sectional depictions of features during fill processes according to various embodiments.

FIG. 6 is a flow diagram showing a method to fill a feature having a protective nitride layer.

FIG. 7A-7E are schematic diagrams showing cross-sectional depictures of a feature with a protective nitride layer during a fill.

FIGS. 8 and 9 show examples of apparatus that may be used to perform the methods described herein.

### DESCRIPTION

Provided are methods of filling features with molybdenum (Mo) films. The Mo films may be deposited in semiconductor substrate features such as vias and trenches as liner layers and feature fill. Applications include sub-10 nm node middle of line (MOL) and back end of line (BEOL) logic interconnects. In one example, the methods may be used for source/drain contact fill.

Mo offers several benefits over other metals such as cobalt (Co), ruthenium (Ru), and tungsten (W): (i) barrier-less and liner-less Mo film deposition is more feasible on oxide and nitride as compared to Co, Ru, and W, (ii) Mo resistivity scaling is better than W, (iii) Mo intermixing with underlying Co is not expected compared to Ru intermixing with Co at less than 450° C., and (iv) there is relatively easy Mo integration into current W schemes compared to Co and Ru.

In some embodiments, the processes include deposition of a thin, protective Mo layer using a molybdenum chloride (MoClₓ) precursor. This may be followed by Mo deposition to fill the feature using a molybdenum oxyhalide (MoO_{y}X_{z}) precursor. The protective Mo layer enables Mo fill using an MoO_{y}X_{z} precursor without oxidation of an underlying surface. This can be useful for oxygen-sensitive surfaces such as silicon (Si), silicon germanium (SiGe), titanium (Ti), titanium nitride (TiN) and titanium silicide (TiSi₂). Also provided are clean and etch processes in which a MoClₓ precursor is used to remove oxide(s) from underlying surfaces prior to deposition. Subsequent deposition using the MoClₓ precursor may yield a liner layer and/or fill a feature. The protective Mo layer protects the bottom surface of the feature. In some embodiments, it is deposited selectively on the bottom surface with little or no deposition on the feature sidewalls. In some embodiments, it is deposited non-selectively on the bottom and sidewall surfaces.

Molybdenum chloride precursors are given by the formula MoClₓ, where x is 2, 3, 4, 5, or 6, and include molybdenum dichloride (MoCl₂), molybdenum trichloride (MoCl₃), molybdenum tetrachloride (MoCl₄), molybdenum pentachloride (MoCl₅), and molybdenum hexachloride (MoCl₆). In some embodiments, MoCl₅ or MoCl₆ are used. While the description chiefly refers to MoClₓ precursors, in other embodiments, other molybdenum halide precursors may be used. Molybdenum halide precursors are given by the formula MoX_{z}, where X is a halogen (fluorine (F), chlorine (Cl), bromine (Br), or iodine (I)) and z is 2, 3, 4, 5, or 6. Examples of MoX_{z} precursors include molybdenum fluoride (MoF₆). In some embodiments, a non-fluorine-containing MoX_{z} precursor is used to prevent fluorine etch or incorporation. In some embodiments, a non-bromine-containing and/or a non-iodine-containing MoX_{z} precursor is used to prevent etch or bromine or iodine incorporation.

Molybdenum oxyhalide precursors are given by the formula MoO_{y}X_{z}, where X is a halogen (fluorine (F), chlorine (Cl), bromine (Br), or iodine (I)) and y and z are numbers greater than 0 such that MoO_{y}X_{z} forms a stable compound. Examples of molybdenum oxyhalides include molybdenum dichloride dioxide (MoO₂Cl₂), molybdenum tetrachloride oxide (MoOCl₄), molybdenum tetrafluoride oxide (MoOF₄), molybdenum dibromide dioxide (MoO₂Br₂), and the molybdenum iodides MoO₂I, and Mo₄O₁₁I.

According to various embodiments, one or more of the following advantages may be realized by the methods described herein. In some embodiments, a single module may be used for both clean of a feature and subsequent deposition in the feature, eliminating a need for a separate clean module. In some embodiments, Mo is deposited without an oxide layer or an oxidized surface at the interface of Mo and an underlying layer. This reduces contact resistance. In some embodiments, a liner layer, such as a titanium nitride (TiN) barrier layer, is etched to reduce its thickness in a well-controlled process. According to various embodiments, the liner layer may be partially or completely removed. This thinning of the liner layer may reduce line and via resistance in the fabricated semiconductor circuit.

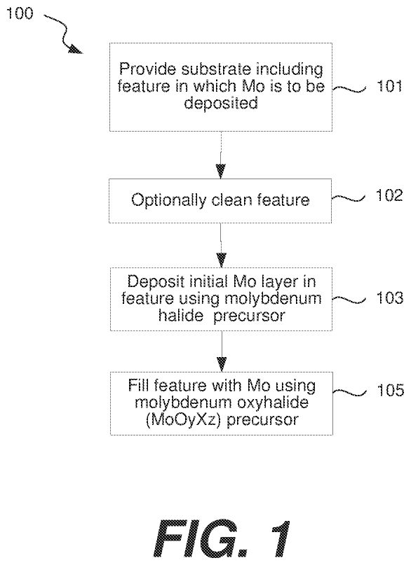

FIG. 1 is a process flow diagram illustrating a method to fill a feature with a molybdenum (Mo) film. Examples of applications include middle-of-line (MOL) or back end of line (BEOL) interconnects. In one example, the methods may be used for source/drain contact fill. Method 100 begins with providing a substrate including a feature in which Mo is to be deposited in an operation 101. The substrate may be provided to a semiconductor processing tool.

The feature may be a trench or via that is formed in a dielectric layer. Examples of dielectric materials include oxides, such as silicon oxide (SiO₂) and aluminum oxide (Al₂O₃); nitrides, such as silicon nitride (SiN); carbides, such as nitrogen-doped silicon carbide (NDC) and oxygen-doped silicon carbide (ODC); and low k dielectrics, such as carbon-doped SiO₂. Mo may be deposited in the feature to make electrical contact to an underlying layer. Examples of underlying layers include metals, metal silicides, and semiconductors. Examples of metals include Co, Ru, copper (Cu), W, Mo, nickel (Ni), iridium (Ir), rhodium (Rh), tantalum (Ta), and Ti. Examples of metal silicides include TiSiₓ, nickel silicide (NiSiₓ), molybdenum silicide (MoSiₓ), cobalt silicide (CoSiₓ), platinum silicide (PtSiₓ), ruthenium silicide (RuSiₓ), and nickel platinum silicide (NiPt_{y}Siₓ). Examples of semiconductors include silicon (Si), silicon germanium (SiGe), and gallium arsenide (GaAs) with or without semiconductor dopants such as carbon (C), arsenic (As), boron (B), phosphorus (P), tin (Sn), and antimony (Sb).

The feature generally has sidewalls with sidewall surfaces and a bottom with a bottom surface. The sidewalls may be made of one or more layers. The sidewall extends from the field to the bottom. The feature bottom may extend from a first sidewall in the feature to a second sidewall in the feature and may be made of one or more layers. The sidewall surface is the exposed area on the sidewall and may change during wafer processing, e.g., the sidewall surface may change from a first material to a second material after the second material is deposited onto the sidewall. Similarly, the bottom surface is the exposed area on the bottom and may change during wafer processing. In some embodiments, the sidewall surfaces may be the same material as the bottom surface. For example, in some embodiments, the sidewall surfaces and the bottom surface are TiN. In some embodiments, the sidewall surfaces may be a different material than the material of the bottom surface. For example, the bottom surface may be a metal silicide and the sidewall surface may be a silicon oxide, such as SiO₂.

Prior to any Mo deposition, a liner layer may line the unfilled feature and form the sidewall surfaces and/or bottom surface. In some embodiments, a liner layer lines the whole feature and forms the sidewall surfaces and bottom surface. In some other embodiments, the liner layer lines only a portion of the feature. For example, a TiN layer may line the sidewalls with the bottom surface unlined. Examples of materials for liner layers include metal nitrides (e.g., a TiN or tantalum nitride (TaN) barrier layer) and metals (e.g., a Ti adhesion layer).

In some embodiments, the bottom and sidewall surfaces are oxidized. Oxidation may be caused by exposing a feature's surfaces to air or other oxidizing conditions. For example, a metal silicide (MSiₓ where M is a metal) surface may be oxidized to oxidized metal silicide (MSiₓO_{y}) on exposure to air. Other examples of oxidized surfaces include oxidized metal nitrides (MNₓO_{y}), oxidized silicon (SiOₓ), and oxidized silicon-germanium (SiGeOₓ). (In the description herein, the subscripts x and y are used in formulas to denote non-zero numbers.)

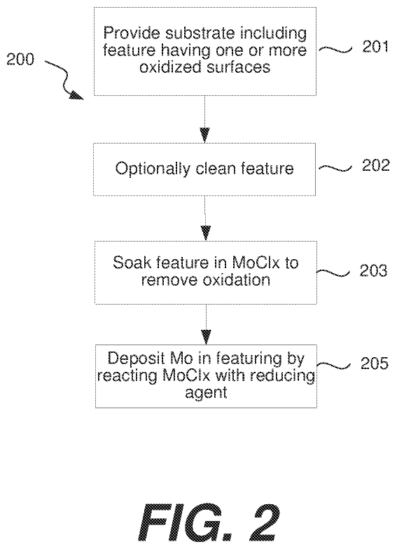

In some embodiments, oxidizing conditions occur in the course of substrate processing or transfer operations. In some embodiments, an intentional oxidation is performed as described further below with reference to FIG. 2.

After providing a substrate including a feature in which Mo is to be deposited, an optional clean, operation 102, may be performed. The optional clean may be used to remove oxide on the feature's surfaces. In some embodiments, a hydrogen plasma treatment, a thermal hydrogen treatment or a reducing treatment, is used to reduce oxidized metal on a metal substrate at the feature bottom. In some embodiments, an atomic layer clean with a Cl-based plasma, a hydrogen fluoride (HF) vapor clean, an ammonium fluoride (NH₄F) clean, or a treatment using other reducing agents may be used to reduce oxide of Si or SiGe on a substrate at the feature bottom. In some embodiments, an in-situ clean using a molybdenum halide, such as molybdenum chloride (MoClₓ), compound may be used. In-situ clean processes are described further below with respect to FIG. 2.

Once the substrate is provided, an initial Mo layer is deposited in the feature in an operation 103. The initial Mo layer may be deposited by an atomic layer deposition (ALD) method. ALD is a surface-mediated deposition technique in which doses of a precursor and a reactant are sequentially introduced into a deposition chamber. The initial Mo layer is deposited by sequentially introducing a Mo precursor and a reducing agent into the deposition chamber. One or more cycles of sequential doses of the Mo precursor and reducing agent may be used to deposit the initial Mo layer. In some embodiments, the initial Mo layer may be deposited conformally to the feature. A conformal Mo layer may be between 1 and 5 nm in some embodiments. In some embodiments, it is no more than 2 nm thick. In some embodiments, Mo may be deposited non-conformally such that it is selectively deposited on the bottom of the feature relative to the sidewalls.

For deposition of the initial Mo layer, the Mo precursor is a MoClₓ precursor. Also as discussed above, other MoX_{z} precursors may be used in other embodiments. Examples of reducing agents include hydrogen (H₂), silane (SiH₄), diborane (B₂H₆), germane (GeH₄), NH₃, and hydrazine (N₂H₄). Using a non-oxygen-containing Mo precursor to deposit the initial Mo layer prevents oxidation of the feature's surfaces. It also prevents oxygen from being incorporated into the initial Mo layer. Oxidation increases contact resistance. The lack of oxidation and oxygen incorporation ensures the contact resistance remains low.

For ALD, the temperature of the substrate and the pressure of a chamber may be controlled. In some embodiments, the substrate may be heated between 300° C. and 500° C., e.g., between 350° C. and 450° C. In some embodiments, the chamber may be pressurized to at least 10 Torr, e.g., to at least 30 Torr, or to at least 50 Torr.

In some embodiments, process parameters such as temperature, may be used to control selectivity. For example, Mo may be deposited selectively on a metal silicide surface or metal nitride surface with respect to a silicon oxide sidewall surface by using a lower temperature than for conformal deposition. For example, in some embodiments, a temperature lower than 400° C. is used.

After the initial Mo layer is deposited, the feature is filled with Mo using a molybdenum oxyhalide (MoO_{y}X_{z}) precursor in operation 105. As indicated above, examples of MoO_{y}X_{z} precursors include MoO₂Cl₂, MoOCl₄, MoOF₄, MoO₂Br₂, MoO₂I, and Mo₄O₁₁I. The feature may be filled using ALD, plasma enhanced ALD, chemical vapor deposition (CVD), or plasma enhanced CVD. In a CVD process, the MoO_{y}X_{z} precursor and a reducing agent are in vapor phase together in the deposition chamber. For ALD or CVD, H₂ may be the reducing agent. Mo deposits more quickly using a molybdenum oxyhalide precursor than the MoClₓ precursor used to form the initial Mo layer. For example, a MoO_{y}X_{z} precursor may deposit Mo at a deposition rate at least twice as fast as a MoClₓ precursor for a non-plasma process. Plasma enhanced processes may be used to fill features at lower temperatures and/or increase deposition rates.

FIG. 2 is a process flow diagram illustrating an in-situ clean method to clean an oxidized feature. Method 200 begins with providing a substrate including a feature having one or more oxidized surfaces in an operation 201. The substrate may be provided to a semiconductor processing tool.

Like the feature referenced in operation 101 of FIG. 1, the feature generally has a bottom surface and sidewall surfaces. It may be formed in a dielectric layer as a trench or via to connect to an underlying layer. Examples of materials that form the bottom surface and sidewall surfaces, including liner layers, are given above with reference to operation 101 of FIG. 1.

The feature has at least one oxidized surface. In some embodiments, both the bottom surface and the sidewall surfaces are oxidized. In some other embodiments, only some surfaces (e.g., only the bottom surface) is oxidized. As described above with reference to FIG. 1, the oxidized surface may be caused by exposing the surface to oxidizing conditions. Examples of oxidizing conditions include exposing the surface to air and treating the surface with an oxygen-based thermal or plasma treatment. In some embodiments, oxidizing conditions occur in the course of substrate processing or transfer operations. In some embodiments, an intentional oxidation is performed as described further below. Examples of oxidized surfaces are given above with reference to FIG. 1.

After providing the substrate, an optional intentional oxidization of the surface may be performed. Intentional oxidation may occur through exposing the surface to air, treating the surface with an oxygen-based thermal treatment or an oxygen-plasma treatment. The intentional oxidation of the surface may be used to increase oxidization of a liner layer, e.g. a TiN barrier layer. This increases the amount of liner layer that is removed during the in-situ clean. Thinning the liner layer in this manner lowers resistance in the feature.

After providing a substrate including a feature in which Mo is to be deposited, an optional clean, operation 202, may be performed. The optional clean may be used to remove oxide on the feature's surfaces. In some embodiments, a hydrogen plasma treatment, a thermal hydrogen treatment or a reducing treatment, is used to reduce oxidized metal on a metal substrate at the feature bottom. In some embodiments, an atomic layer clean with a Cl-based plasma, a hydrogen fluoride (HF) vapor clean, an ammonium fluoride (NH₄F) clean, or a treatment using other reducing agents may be used to reduce oxide of Si or SiGe on a substrate at the feature bottom.

Next, the feature undergoes a soak in an operation 203. The feature is soaked in a molybdenum chloride (MoClₓ) precursor to remove oxidation from the feature's surfaces. In some embodiments, the soak may be done continuously. In some embodiments, the soak may be pulsed, cycling MoClₓ and a purge gas, such as argon (Ar). The precursor is a non-oxygen Cl-containing Mo compound able to remove oxidation from the feature's surfaces. Examples of MoClₓ compounds are given above. A Cl-containing precursor may be used where traditional cleaning with thermal or plasma H₂ does not work, such as where the oxidized surface is stable on the surface material. A Cl-containing precursor is less likely to over-etch a feature's liner layer or attack a feature's surfaces than a F-containing compound.

In one example, a feature may have a TiN barrier layer as its liner layer. The liner layer may be oxidized to form a TiNₓO_{y} surface layer. Because TiNₓO_{y} is stable, H₂ processes may not efficiently remove TiNₓO_{y} from the TiN layer. Soaking the feature in a MoClₓ precursor, such as MoCl₅, effectively removes the oxide from the TiN liner layer. For relatively thin liners, a F-based precursor, such as tungsten fluoride (WF₆), may cause over-etching of the liner. The F-based precursor may attack the underlying surfaces, such as the feature's bottom surface. The in-situ clean process of FIG. 2 prevents over-etching of the TiN liner and attack on the underlying surfaces. In an example of a TiN barrier layer, the F-based precursor may attack it and/or any underlying metal silicide.

For the in-situ clean, the temperature of the substrate, the pressure of a chamber in the semiconductor processing tool, and the precursor exposure time to the feature may be controlled. In some embodiments the substrate may be heated between 300° C. and 500° C., e.g., between 350° C. and 450° C. In some embodiments, the chamber may be pressurized to at least 10 Torr, e.g., at least 30 Torr, or at least 50 Torr. The total precursor exposure time to the feature may be at least 10 seconds, e.g., at least 60 seconds. As indicated above, the soak may be continuous or pulsed.

After the feature undergoes a soak and oxidation is removed from the feature's surfaces, the feature may be filled with Mo in an operation 205. Operation 205 may involve deposition of an initial Mo layer and/or fill using MoClₓ, the same precursor used to soak the feature in operation 203. In some other embodiments, the feature may be filled using a molybdenum oxyhalide precursor MoCl_{y}X_{z}. Examples of Mo oxyhalide precursors are given above. The feature may be filled using ALD or CVD, including thermal and plasma-enhanced ALD and CVD processes.

Feature fill may be non-selective or selective according to various embodiments. In some embodiments, feature fill may be selective to partially fill the feature, followed by a more conformal fill to complete feature fill. A non-selective deposition may be described herein as a conformal deposition in that the deposited layer conforms to the contour of the underlying feature. Such a deposited layer may have some thickness non-uniformity.

In some embodiments, the feature may be filled by ALD, first using the MoClₓ precursor to deposit an initial Mo layer on the feature's surfaces. After the initial Mo layer is deposited, the fill may continue with ALD using a Mo oxyhalide precursor for Mo bulk fill. In some embodiments, the feature may be filled using the MoClₓ precursor in a single fill operation. In other embodiments, operations 103 and 105 as described in FIG. 1 may be performed.

For the fill process in operation 205, the temperature of the substrate, the pressure of the chamber may be controlled, and the reactant exposure time may be controlled. As in operation in 203, the substrate may be heated between 300° C. and 500° C., e.g., between 350° C. and 450° C. The chamber may be pressurized to at least 10 Torr, e.g., at least 30 Torr, or at least 50 Torr. The reactant exposure time may be at least 5 seconds, e.g., at least 15 seconds.

In some embodiments, process parameters, such as temperature, may be used to control selectivity. For example, Mo may be deposited selectively on a metal silicide surface or metal nitride surface with respect to a silicon oxide sidewall surface by using a lower temperature than for conformal deposition.

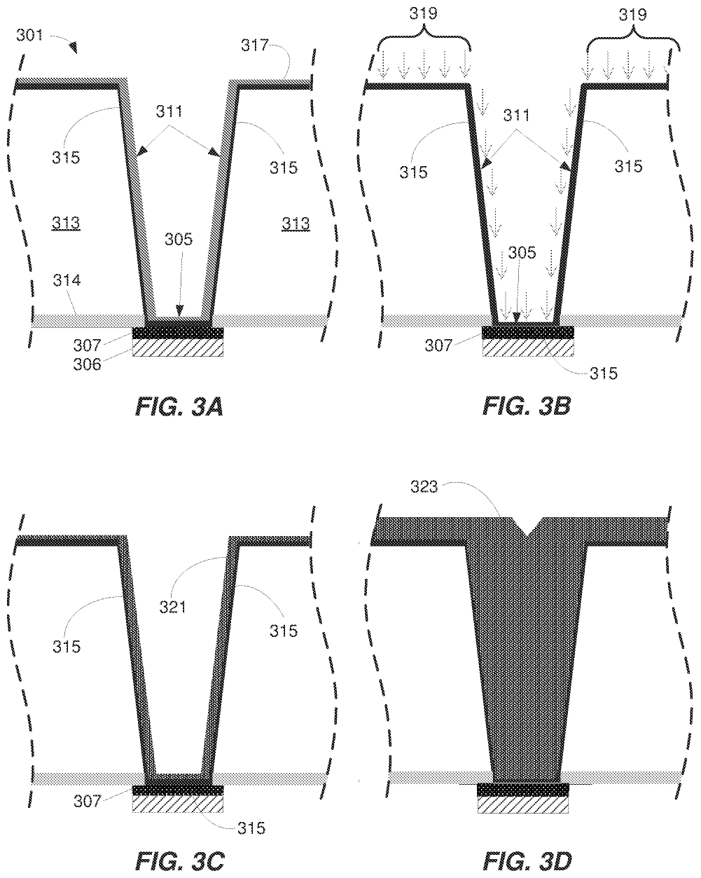

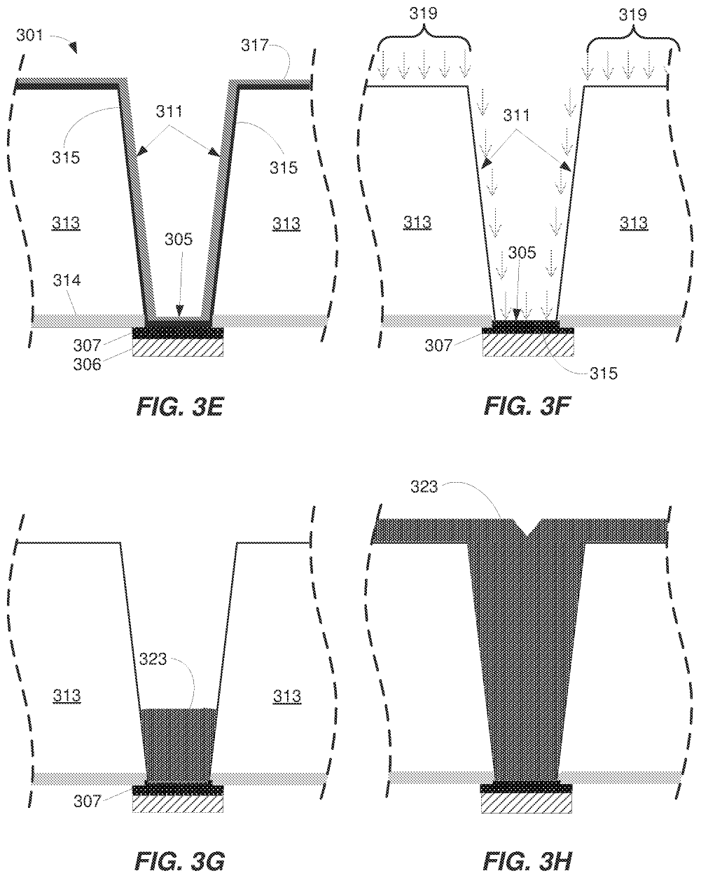

FIGS. 3A-5D show schematic examples of the processes of FIG. 1 and/or FIG. 2. In FIG. 3A, a feature 301 having a TiN liner layer 315 is shown. The feature 301 is formed in a dielectric material 313 to connect to an underlying metal silicide (MSiₓ) 307. The underlying MSiₓ is connected to a semiconductor layer 306, e.g., silicon (Si) or silicon-germanium (SiGe). This stack may be used in a transistor junction structure. In the example of FIG. 3A, the dielectric material 313 is mostly oxide and includes a nitride layer 314. One example of a MSiₓ layer is titanium silicide (TiSiₓ).

The TiN liner layer 315 lines the feature 301. The TiN liner layer 315 is a barrier layer used on top of a metal silicide such as TiSiₓ in trench contacts for source/drain applications. One purpose of the TiN layer is to prevent the MSiₓ from any potential reaction with the overlying metal. Another purpose is to protect the MSiₓ or a Mo diffusion barrier from a fluorine attack. Yet another purpose is to prevent the MSiₓ from being oxidized in air or during subsequent processing. However, when the TiN layer is exposed to air, TiN surface oxide (i.e., TiNₓO_{y}) is formed. TiNₓO_{y} is not easy to reduce by a thermal or plasma H₂ preclean process. And even if TiNₓO_{y} is fully reduced by a preclean process, the TiN surface is susceptible to re-oxidation in subsequent Mo deposition. Re-oxidation increases contact resistance. The methods described herein allow Mo deposition without this increase in contact resistance. Further, the methods described herein allow thinning of the TiN thickness, further reducing resistance.

At least the top surface of the TiN liner layer 315 is oxidized. The oxidized TiN is TiNₓO_{y} 317 and forms bottom surface 305 and sidewall surfaces 311. FIG. 3B depicts the feature 301 undergoing an in-situ clean, as described above in FIG. 2. Shown is a MoClₓ precursor 319 soaking the feature. In some embodiments, the soak is continuous. In some embodiments, the soak may be multiple cycles of alternating doses of the MoClₓ precursor and a purge gas. The MoClₓ precursor soak effectively removes the oxide from the surface. The TiNₓO_{y} 317 layer is etched, and the TiN remains. Once the in-situ clean is completed, the unoxidized TiN liner layer 315 forms the bottom surface 305 and sidewall surfaces 311 of the feature 301. The unoxidized TiN liner layer 315 may be about 1-10 Angstroms thick in some embodiments.

FIG. 3C shows the feature 301 after an initial Mo layer 321 is deposited. As described in FIG. 1, the initial Mo layer 321 is deposited using an ALD process. In the example of FIG. 3C, the ALD process uses the MoClₓ precursor, the same precursor used in the in-situ clean shown in FIG. 3B. The result is a thin initial Mo layer 321 non-selectively deposited on the TiN liner layer 315. The initial Mo layer 321 may be less than 5 nm thick or less than 2 nm thick in some embodiments. The precursor is non-oxygen containing molybdenum precursor. Thus, as shown in FIG. 3C, there is no re-oxidation of the feature 301. Nor is the initial Mo layer 321 oxidized. The feature is left with an unoxidized TiN liner layer 315 covered by an unoxidized initial Mo layer 321.

In FIG. 3D, feature 301 after Mo gap fill is shown. The feature is filled with Mo 323. The feature may be filled using the ALD or a CVD process. The Mo gap fill is deposited on the initial Mo layer 321 to the top of the feature. As described in FIG. 1, the gap fill uses a Mo oxyhalide precursor. While the Mo oxyhalide precursor contains oxygen, the initial Mo layer 321 prevents oxidation of the TiN liner layer 315. In the case that the TiN layer 315 is completely removed, the initial Mo layer 321 prevents oxidation of the MSiₓ layer. In some embodiments, the gap fill may continue to use the MoClₓ precursor.

As discussed above, in some embodiments, deposition of Mo in the feature may be selective to the bottom surface when the TiN layer 315 is completely removed, thus exposing the sidewall SiO₂ 313 and the MSiₓ layer 307. This results in bottom-up rather than conformal fill and can be useful to prevent seam and void formation. An example of selective deposition is described below with respect to FIGS. 3E-3H.

FIG. 3E shows a feature 301 having a TiN liner layer 315. The feature 301 is formed in a dielectric material 313 to connect to an underlying MSiₓ 307. The underlying MSiₓ is connected to a semiconductor layer 306, e.g., Si or SiGe. The dielectric material 313 is mostly oxide and includes a nitride layer 314. The TiN liner layer 315 covers the feature. At least the top layer of the TiN liner layer is oxidized and forms a TiNₓO_{y} 317 layer. The TiNₓO_{y} layer forms bottom surface 305 and sidewall surfaces 311.

FIG. 3F depicts the feature 301 undergoing an in-situ clean. Shown is a MoClₓ precursor 319 soaking the feature. The MoClₓ precursor soak effectively removes the oxide and the TiN liner layer 317 from both the bottom surface 305 and sidewall surfaces 311. Both the TiNₓO_{y} 317 layer and the TiN liner layer 315 are etched away. The in-situ clean exposes the dielectric material 313 as the sidewall surfaces 311 and the underlying MSiₓ 307 as the bottom surface 305.

FIG. 3G depicts the feature 301 after Mo 323 is selectively deposited. The Mo 323 may be deposited using an ALD process or a CVD process. In some embodiments, the ALD process uses the MoClₓ precursor, the same precursor used in the in-situ clean shown in FIG. 3F. The result is Mo 323 selectively deposited on the underlying MSiₓ 307. Selective deposition refers to depositing more Mo 323 on the metal-containing surfaces, MSiₓ, relative to the dielectric material 313 surfaces. In some embodiments, no Mo or only a discontinuous film of Mo is deposited on the dielectric material surfaces. As described with respect to FIG. 3C, the precursor is a non-oxygen containing Mo precursor, thus there is no re-oxidation of the feature 301, nor is the Mo 323 oxidized. The feature is left with Mo deposited on the bottom surface 305.

FIG. 3H shows the feature 323 after the Mo gap filled. The feature is filled with Mo 323 from the initial Mo deposition to the top of the feature. The feature may be filled using the ALD or the CVD process. In some embodiments, the fill may be performed in a single stage deposition, where the fill is continued using the same parameters, such as temperature and pressure, as the initial fill in FIG. 3F. In some other embodiments, the fill may be performed in multi-stage Mo deposition. In a multi-stage deposition, the deposition may change parameters during the deposition. For example, the selective deposition occurring in a first stage may have a first temperature. After the selective deposition in the first stage, the deposition may continue in a second stage and may have a second temperature higher than the first temperature. The increase in temperature may be used to increase the rate of Mo bulk fill, decreasing processing time. Selective Mo deposition can also be achieved by varying other process parameters in a multi-stage configuration. For example, in some embodiments, the Mo precursor and reactant concentrations are varied at different stages. In some embodiments, operating in a starved Mo precursor regime may result in higher selectivity in certain embodiments. In some embodiments, deposition at a particular condition may initially be selective and transition to a non-selective deposition as the exposure time increases and a nucleation delay is overcome. Thus, a selective deposition may involve limiting exposure time.

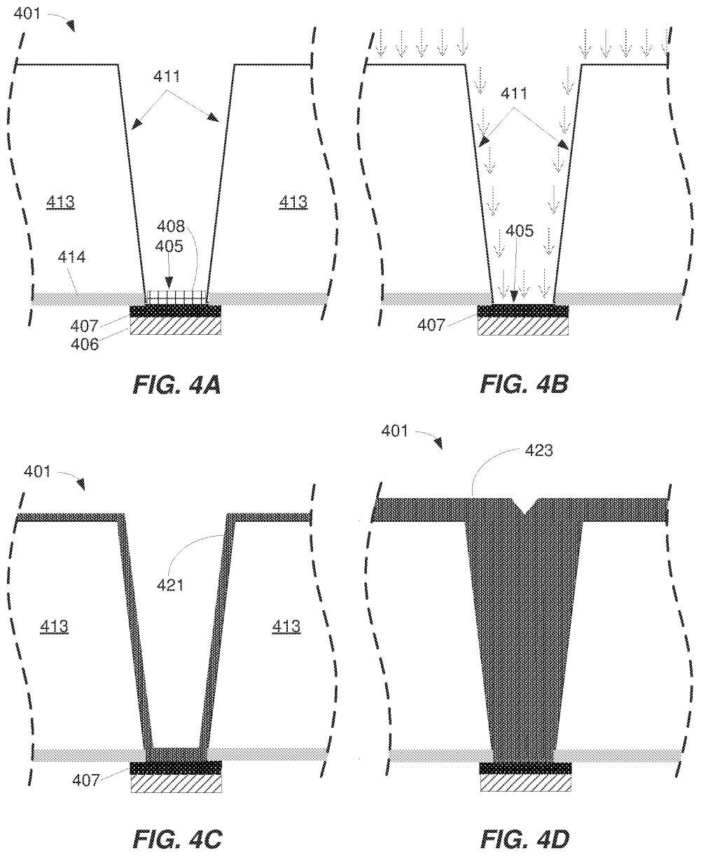

In FIG. 4A, a feature 401 is shown. The feature 401 is formed in a dielectric material 413 to connect to an underlying titanium silicide (TiSiₓ) 407. The underlying TiSiₓ is connected to a semiconductor layer 406, e.g., silicon (Si) or silicon-germanium (SiGe). This stack may be used in a transistor junction structure. The dielectric material 413 is mostly oxide, includes a nitride layer 414, and forms the sidewall surfaces 411. In some embodiments, the sidewall surfaces 411 may be coated with a Ti liner layer (not shown). At least the top surface of the underlying TiSiₓ 407 is oxidized. The oxidized TiSiₓ is titanium silicide oxide TiSiₓO_{y} 408 and forms a bottom surface 405.

FIG. 4B depicts the feature 401 undergoing a preclean process. The preclean process may be an atomic layer clean with a Cl-based plasma, a hydrogen fluoride (HF) vapor clean, an ammonium fluoride (NH₄F) clean, or a treatment using other reducing agents. The preclean is an integrated process (no vacuum break) which removes the oxide from the surface. The TiSiₓO_{y} 408 layer is removed, exposing the underlying TiSiₓ 407 as the bottom surface 405.

FIG. 4C shows the feature 401 after the initial Mo layer 421 is deposited. The initial Mo layer 421 is deposited using an ALD process using a MoClₓ precursor. The result is an initial Mo layer 421 non-selectively deposited, including directly on the dielectric material 413 and on the underlying TiSiₓ 407. The initial Mo layer 421 may be less than 5 nm thick layer. The precursor is non-oxygen containing. Thus, as shown in FIG. 4C, there is no re-oxidation of the feature 401. Nor is the initial Mo layer 421 oxidized. The feature is left with an unoxidized underlying TiSix. The initial Mo layer 421 conformally covers the dielectric material 413 on the feature sidewalls and the TiSiₓ 407 on the feature bottom.

FIG. 4D depicts feature 401 after Mo gap fill. The feature is filled with Mo 423. The feature may be filled using ALD, plasma enhanced ALD, CVD or plasma enhanced CVD. The Mo gap fill is deposited on the initial Mo layer 421 to the top of the feature. The gap fill uses a Mo oxyhalide precursor. While the Mo oxyhalide precursor contains oxygen, the initial Mo 421 prevents oxidation of the Ti liner layer and the underlying TiSiₓ. While the example in FIG. 4C shows the initial Mo layer 421 as a conformal layer, in other embodiments, it may be deposited selectively as in FIG. 3G. In such cases, the Mo gap fill is bottom up fill as in FIG. 3H.

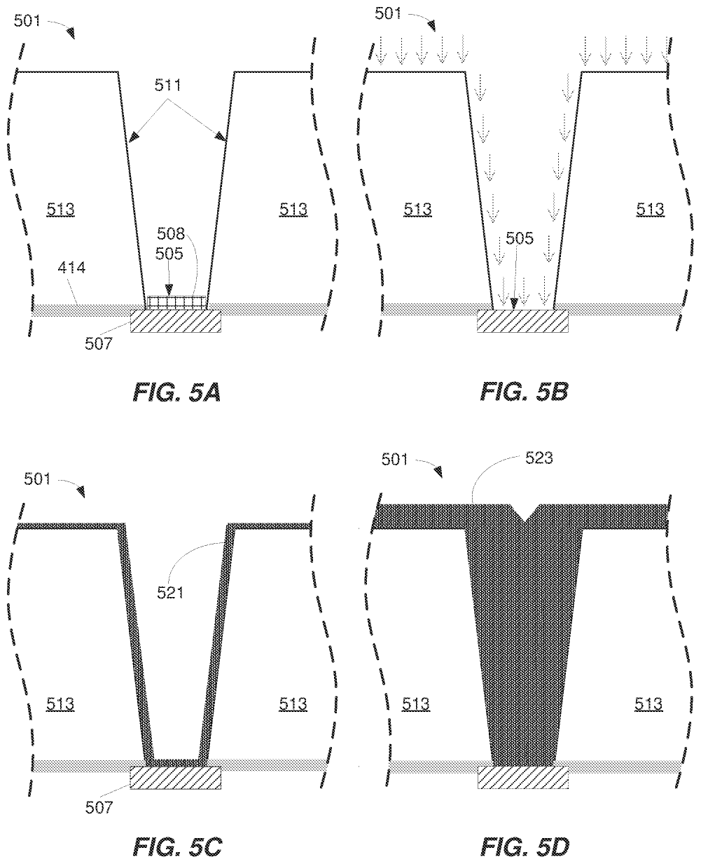

FIG. 5A shows a feature 501 without a liner layer. The feature is formed in a dielectric material 513 to connect to an underlying semiconductor 507, such as Si or SiGe. At least the top surface of the semiconductor surface is oxidized to form a bottom surface 505. For example, the semiconductor surface Si is oxidized to form silicon oxide (SiOₓ) 508. The dielectric material 513 forms sidewall surfaces 511. It is mostly oxide and includes a nitride layer 514.

FIG. 5B depicts the feature 501 undergoing a preclean process. As described in FIGS. 1 and 2 as an optional preclean process, the preclean process may be an atomic layer clean with a Cl-based plasma, HF vapor clean, an ammonium fluoride clean, or a treatment using other reducing agents. The preclean process removes the oxide from the semiconductor surface and the semiconductor surface forms the bottom surface 505. For example, the SiOₓ 508 layer is converted to Si, which forms the bottom surface 505. In another embodiment, the preclean process can be a MoClₓ soak process. FIG. 5B can also depict a MoClₓ precursor soaking the feature. In some embodiments, the soak is continuous. In some embodiments, the soak may be multiple cycles of alternating doses of the MoClₓ precursor and a purge gas. The MoClₓ precursor soak effectively removes the oxide 508 from the Si (and SiGe) surface 508.

FIG. 5C shows the feature 501 after an initial Mo layer 521 is deposited. The initial Mo layer 521 is deposited using an ALD process. In the example of FIG. 5C, the ALD process uses a MoClₓ precursor. The result is a thin initial Mo layer 521 conformally deposited on the feature 501, including directly on the dielectric material 513 and on the underlying semiconductor 507. The initial Mo layer may be less than 5 nm thick. The precursor is non-oxygen containing molybdenum precursor. Thus, as shown in FIG. 5C, there is no re-oxidation of the feature 501. Nor is the initial Mo layer 521 oxidized. The feature is left with an unoxidized underlying semiconductor 507 and the dielectric material 513 conformally covered by an unoxidized initial Mo layer 521.

FIG. 5D depicts feature 501 after Mo gap fill. The feature is filled with Mo 523. The feature may be filled using ALD, plasma enhanced ALD, CVD or plasma enhanced CVD. The Mo gap fill is deposited on the initial Mo layer 521 to the top of the feature. The gap fill uses a Mo oxyhalide precursor. While the Mo oxyhalide precursor contains oxygen, the initial Mo layer 521 prevents oxidation of the dielectric material and the underlying semiconductor surface.

While the example in FIG. 5C shows the initial Mo layer 521 as a conformal layer, in other embodiments, it may be deposited selectively as in FIG. 3G. In such cases, the Mo gap fill is bottom up fill as in FIG. 3H.

The features that may advantageously filled with Mo using the methods of FIGS. 1 and/or 2 are not limited to the examples in FIGS. 3A-3H. Features having other bottom and/or sidewalls surfaces may be cleaned in-situ and/or be filled using a MoClₓ precursor. In one example, a bottom surface may be an oxidized metal surface such as a Mo, W, Co, Cu, or Ti surface that is oxidized. An in-situ clean may be performed to remove the oxidation, leaving a unoxidized metal surface.

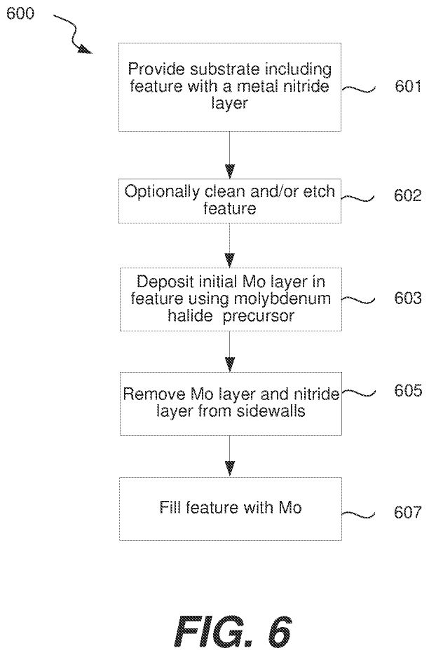

FIG. 6 is a process flow diagram illustrating a method to fill a feature having a protective nitride layer with a molybdenum (Mo) film. The protective nitride layer may be used to protect a feature bottom and the underlying materials below a bottom surface of the feature. Method 600 begins with providing a substrate with a metal nitride layer in operation 601. The substrate may be provided to a semiconductor processing tool.

Similar to the feature referenced in operation 101 of FIG. 1, the feature generally has a bottom with a bottom surface and sides with sidewall surfaces. It may be formed in a dielectric layer as a trench or via and connects to an underlying layer. Examples of materials that form the bottom and sidewall are given above with reference to operation 101 in FIG. 1.

In the feature provided, the bottom surface is a metal nitride layer. Examples of a metal nitride are TiN and TiSiN. In some embodiments, the metal nitride layer may conformally line the feature, such that the sidewall surfaces and bottom surface is the metal nitride layer. In some embodiments, the sidewall surfaces may be a different material than the material of the bottom surface. For example, the bottom surface may be a metal nitride layer and the sidewall surface may be a dielectric material.

In some embodiments, the bottom surface and sidewall surfaces are oxidized. Oxidation may be caused by exposing a feature's surfaces to air or other oxidizing conditions. In some embodiments, oxidizing conditions occur in the course of substrate processing or transfer operations. In some embodiments, an intentional oxidation is performed as described above with reference to FIG. 2.

After providing a substrate with a metal nitride layer, an optional clean and/or optional etch may be performed in operation 602. The clean may be used to remove oxide from the field, sidewall surfaces, and bottom surfaces of the feature while the optional etch may be used to remove part of the metal nitride layer on the sidewall or the field of the substrate. Examples of cleaning treatments are given above in operation 202 of FIG. 2.

If performed, operation 602 may involve soaking the feature in a Mo precursor to remove oxidation and/or remove or reduce the metal nitride layer from the feature. In some embodiments, the soak may be done continuously. In some embodiments, pulsed soak may be used, cycling the precursor gas while flowing a purge gas. In some embodiments, the precursor gas may be cycled alternatively with a purge gas. In some embodiments, the precursor gas is MoClₓ, e.g., precursor gas is MoCl₅. Examples of other MoClₓ precursors are given above.

For the clean/etch operation in 602, the temperature of the substrate, the pressure of a chamber in the semiconductor processing tool, and the precursor exposure time to the feature may be controlled. In some embodiments the substrate may be heated between 300° C. and 500° C., e.g., between 350° C. and 450° C. In some embodiments, the chamber may be pressurized to at least 10 Torr, e.g., at least 30 Torr, or at least 50 Torr. The total precursor exposure time to the feature may be at least 10 seconds, e.g., at least 60 seconds. As indicated above, the soak may be continuous or pulsed.

In an operation 603, an initial Mo layer is deposited into the feature. The initial Mo layer may be deposited by ALD. The initial Mo layer is formed by depositing one or more sequential doses of the Mo precursor and a reducing agent into the deposition chamber. The Mo precursor may be a non-oxygen containing Mo precursor. The non-oxygen containing precursor prevents oxidation of the surfaces of the feature and helps ensure the contact resistance remains low. An example of a non-oxygen containing precursor is a MoClₓ precursor, which are described above. Examples of reducing agents are given above in operation 103 of FIG. 1. The initial Mo layer may be deposited selectively into the feature on the metal nitride layer. The Mo is deposited so that the Mo layer becomes the bottom surface of the feature. The conformal Mo layer may be between 1 and 5 nm in some embodiments. In some embodiments, it is no more than 2 nm thick

For ALD, the temperature of the substrate and the pressure of a chamber may be controlled. In some embodiments, the substrate may be heated between 300° C. and 500° C., e.g., between 350° C. and 450° C. In some embodiments, the chamber may be pressurized to at least 10 Torr, e.g., to at least 30 Torr, or to at least 50 Torr.

After the Mo layer is deposited, the Mo layer and the underlying metal nitride layer are removed from at least a portion of the sidewalls of the feature. Operation 605 may involve performing an etch operation similar to that described above with respect to operation 602. The etch is performed such that the metal nitride layer and the Mo layer on the bottom surface remain in the feature. The metal nitride layer and the Mo layer on the feature bottom surface may be used to protect an active junction on the feature bottom. The etch may use the same precursors and the same methods described in the etch operation above described in operation 602. The etch in operation 605 may be “more aggressive” than the clean and/or etch performed in operation 602. A more aggressive etch in operation 605 may be performed at a higher temperature, higher pressure, longer exposure time of the precursor, or a combination thereof than that in operation 602.

The feature is filled with Mo in operation 607 after the metal nitride layer and Mo layer are removed from the sidewalls of the feature in operation 605. The feature may be filled by using ALD or CVD, including thermal and plasma-enhanced ALD and CVD processes. A Mo halide or Mo oxyhalide may be used as a precursor for the fill operation. In some embodiments, multiple precursors may be used to fill the feature. In one such embodiment, a Mo halide precursor may be used to deposit Mo into the feature followed by a Mo oxyhalide precursor for a bulk Mo fill. For example, the feature may be initially filled using MoCl₅ as a precursor followed by a fill using MoO₂Cl₂. Examples of Mo halide precursors and Mo oxyhalide precursors are described above. The feature fill may be non-selective or selective according to various embodiments. In some embodiments, feature fill may be selective to partially fill the feature, followed by a more conformal fill to complete feature fill.

The fill process may use the same parameters discussed above in FIG. 2. Similar to the operation in 203, the substrate may be heated between 300° C. and 500° C., e.g., between 350° C. and 450° C. The chamber may be pressurized to at least 10 Torr, e.g., at least 30 Torr, or at least 50 Torr. The reactant exposure time may be at least 5 seconds, e.g., at least 15 seconds. In some embodiments, process parameters, such as temperature, may be used to control selectivity.

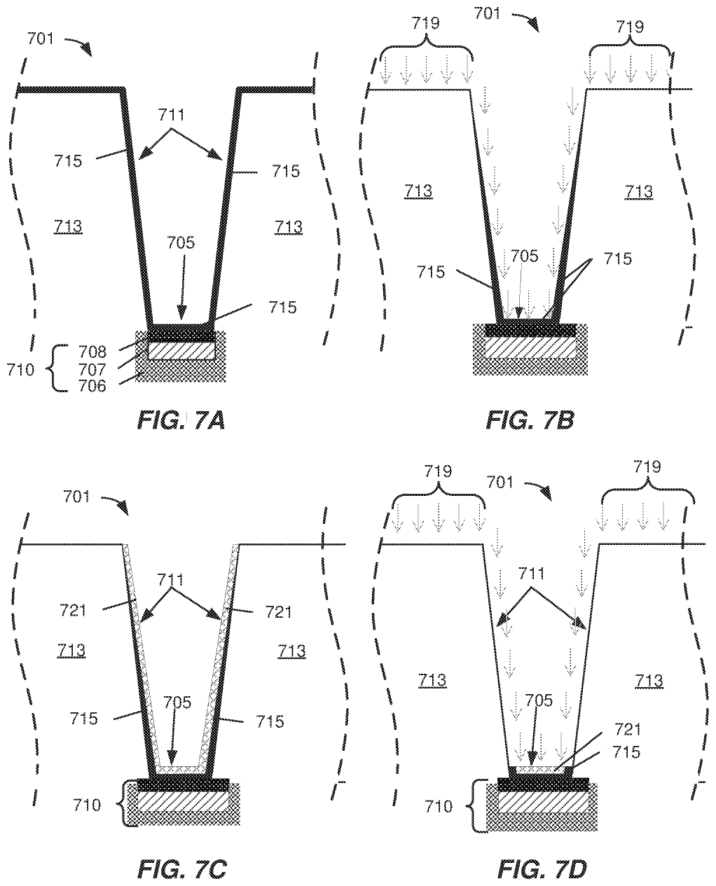

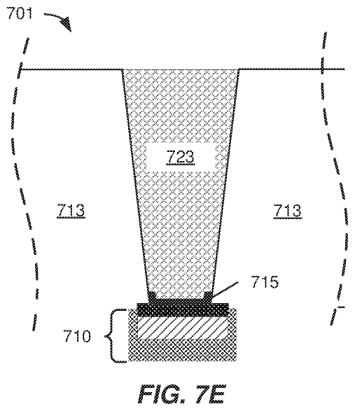

FIGS. 7A-7F show schematic examples of the process of FIG. 6. In FIG. 7A, a feature 701 having a TiN liner layer 715 is shown. The feature 701 has a bottom surface 705 and sidewall surfaces 711. In FIG. 7A, the TiN liner is the bottom surface 705 and the sidewall surfaces 711. In some embodiment, the liner layer may be a titanium silicon nitride (TiSiₓN) liner layer. In some embodiments, the TiN layer 715 may be oxidized on a top surface of the layer. The feature 701 is formed in a dielectric material 713. An underlying stack 710 is below the feature bottom surface 705. In the example shown, the underlying stack 710 has a metal silicide nitride (MSiₓN_{y}) layer 708 and a metal silicide layer (MSiₓ) 707 connected to a semiconductor layer 706, e.g., silicon (Si) or silicon-germanium (SiGe). This stack 710 may be used in a transistor junction structure. One example of a MSiₓ layer is titanium silicide (TiSiₓ) and a metal silicide nitride (MSiₓN_{y}) is a titanium silicide nitride (TiSiₓN_{y}). The TiN liner layer 715 on the bottom surface 705 is used to protect the underlying stack 710 below the feature bottom surface. As discussed above with respect to FIG. 3A, the TiN liner layer may act as a diffusion barrier, prevent etching of the underlying material, and prevent the underlying material from oxidizing.

FIG. 7B depicts the feature 701 undergoing a clean and etch process, as described above in operation in 602 of FIG. 6. Shown is a MoClₓ precursor 719 soaking the feature. The MoClₓ precursor 719 soak effectively removes any oxide on the surface. For example, TiNₓO_{y} may be cleaned and may leave a TiN layer 715. The etch removes any TiN layer on the field and may remove part or all of the TiN layer on the substrate sidewall. In the embodiment shown, part of the TiN layer 715 remains on the sidewalls such that the TiN layer is thicker at the bottom portion of the sidewall relative to the upper portion. The TiN layer remains as the bottom surface 705 and may be the thickest portion of the remaining TiN layer in the feature 701. The TiN layer remains as the bottom surface 705 to protect the underlying stack 710 during subsequent processing.

FIG. 7C shows the feature 701 after an initial Mo layer 721 is deposited. The Mo layer 721 is deposited using an ALD process using a Mo halide precursor such as MoCl₅ with a reducing agent. As shown, the initial Mo layer 721 is selectively deposited on the TiN layer 715 in the feature and covers the sidewalls and the feature bottom. The Mo layer 721 is deposited directly on the TiN layer 715 and not on any dielectric surface.

FIG. 7D shows the feature 702 after a second etch process in operation 605 in FIG. 6. The etch process may be similar to the clean and etch process used in FIG. 7B. The feature 701 may undergo a soak process with an MoClₓ precursor 719. In some embodiments, the soak may be continuous. In still some other embodiments, the soak may be multiple cycles of alternating doses of the MoClₓ precursor and a purge gas. As discussed above in operation 605 of FIG. 6, the etch in 7D may be a more aggressive etch than the etch shown in 7B. The etch removes the Mo layer and the TiN layer on the sidewalls of the feature. As shown, the dielectric material 713 forms the sidewall surfaces 711 after the etch. The etch leaves the TiN layer 715 and the Mo layer 721 on the bottom of the feature 701 so that they form the bottom surface 704 and protect the underlying stack 710. The clean removes any oxide or contaminants on the surfaces.

FIG. 7E shows the feature 701 after a Mo gap fill of the feature. The feature 701 is filled with a Mo fill 723. The TiN layer 715 remains between the Mo fill 723 and the underlying stack 710. The feature 701 may be filled using an ALD or a CVD process. The fill may be done with a Mo oxyhalide precursor containing oxygen, a Mo halide precursor not containing oxygen, or a combination thereof. In some embodiments, the fill may be a conformal fill followed by gap fill as discussed above with respect to FIGS. 3C and 3D. In some embodiments, the fill may be a bottom-up fill as discussed above with respect to FIGS. 3G and 3H. In some embodiments, the fill may be performed in a single stage deposition, where the fill is continued using the same parameters, such as temperature and pressure, as the initial fill. In some other embodiments, the fill may be performed in multi-stage Mo deposition, where parameters may be changed during the deposition. For example, the deposition at a first stage may have a first temperature. After the first stage, the deposition may continue in a second stage and may have a second temperature higher than the first temperature. The increase in temperature may be used to increase the rate of Mo bulk fill, decreasing processing time. In another example of multi-stage deposition, the Mo precursor and reactant concentrations may be varied at different stages.

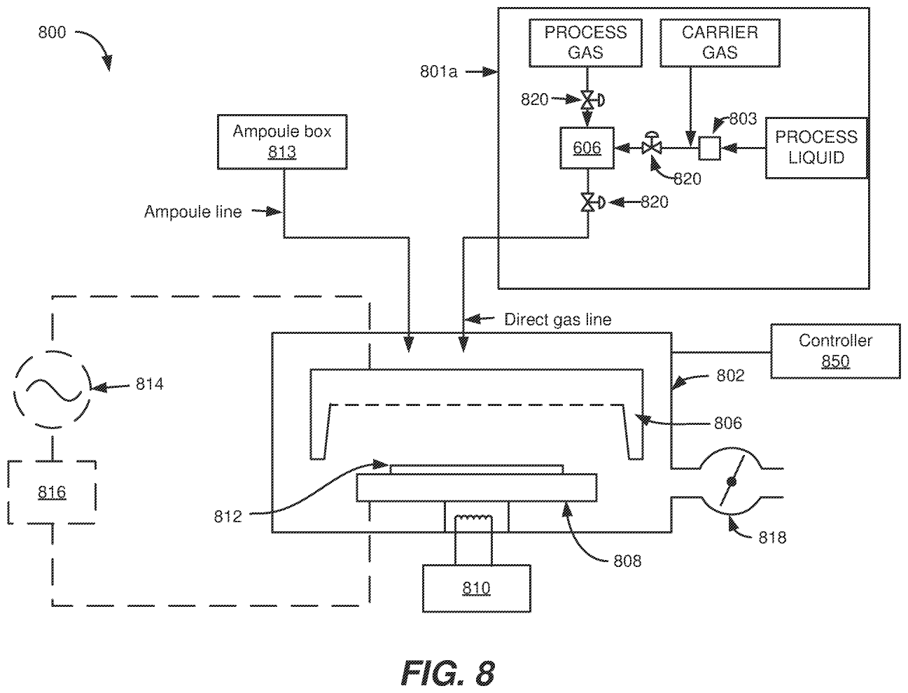

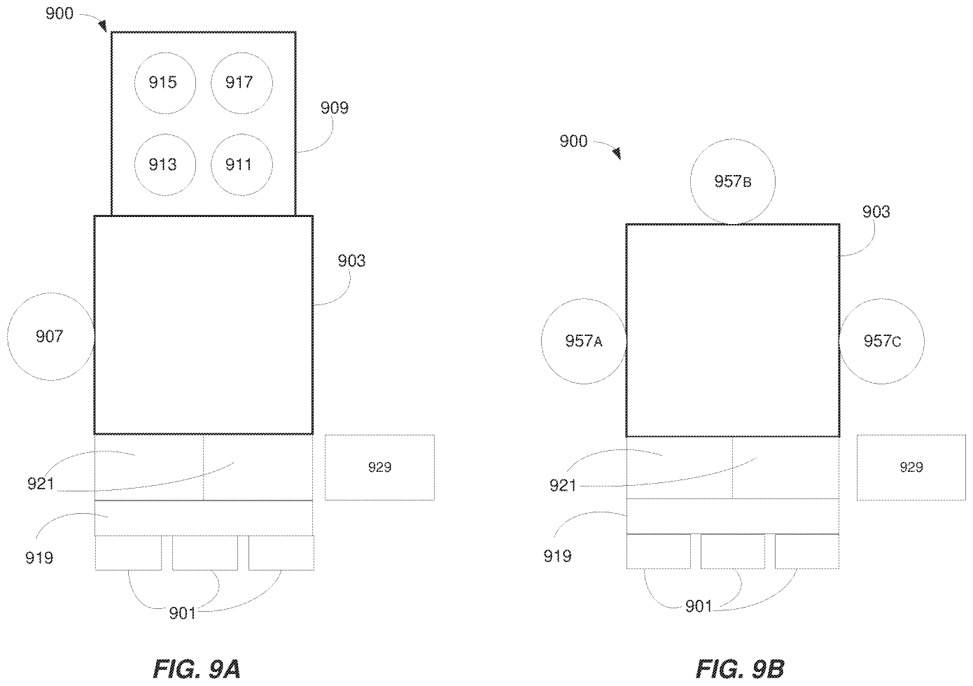

FIG. 8 depicts a schematic illustration of an embodiment of an ALD process station 800 having a process chamber 802 for maintaining a low-pressure environment. In some embodiments, a plurality of ALD process stations may be included in a common low-pressure process tool environment. For example, FIG. 9 depicts an embodiment of a multi-station processing tool 900. In some embodiments, one or more hardware parameters of ALD process station 800, including those discussed in detail below, may be adjusted programmatically by one or more computer controllers 850. In some other embodiments, a process chamber may be a single station chamber.

ALD process station 800 fluidly communicates with reactant delivery system 801a for delivering process gases to a distribution showerhead 806. Reactant delivery system 801a includes a mixing vessel 804 for blending and/or conditioning process gases, such as a Mo precursor-containing gas, a hydrogen-containing gas, an argon or other carrier gas, or other reactant-containing gas, for delivery to showerhead 806. One or more mixing vessel inlet valves 820 may control introduction of process gases to mixing vessel 804. In various embodiments, deposition of an initial Mo layer is performed in process station 800 and in some embodiments, other operations such as in-situ clean or Mo gap fill may be performed in the same or another station of the multi-station processing tool 800 as further described below with respect to FIG. 9.

As an example, the embodiment of FIG. 8 includes a vaporization point 803 for vaporizing liquid reactant to be supplied to the mixing vessel 804. In some embodiments, vaporization point 803 may be a heated vaporizer. In some embodiments, a liquid precursor or liquid reactant may be vaporized at a liquid injector (not shown). For example, a liquid injector may inject pulses of a liquid reactant into a carrier gas stream upstream of the mixing vessel 804. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 803. In one scenario, a liquid injector may be mounted directly to mixing vessel 804. In another scenario, a liquid injector may be mounted directly to showerhead 806.

In some embodiments, a liquid flow controller (LFC) upstream of vaporization point 803 may be provided for controlling a mass flow of liquid for vaporization and delivery to process chamber 802. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 806 distributes process gases toward substrate 812. In the embodiment shown in FIG. 8, the substrate 812 is located beneath showerhead 806 and is shown resting on a pedestal 808. Showerhead 806 may have any suitable shape and may have any suitable number and arrangement of ports for distributing process gases to substrate 812.

In some embodiments, pedestal 808 may be raised or lowered to expose substrate 812 to a volume between the substrate 812 and the showerhead 806. In some embodiments, pedestal 808 may be temperature controlled via heater 810. Pedestal 808 may be set to any suitable temperature, such as between about 300° C. and about 500° C. during operations for performing various disclosed embodiments. It will be appreciated that, in some embodiments, pedestal height may be adjusted programmatically by a suitable computer controller 850. At the conclusion of a process phase, pedestal 808 may be lowered during another substrate transfer phase to allow removal of substrate 812 from pedestal 808.

In some embodiments, a position of showerhead 806 may be adjusted relative to pedestal 808 to vary a volume between the substrate 812 and the showerhead 806. Further, it will be appreciated that a vertical position of pedestal 808 and/or showerhead 806 may be varied by any suitable mechanism within the scope of the present disclosure. In some embodiments, pedestal 808 may include a rotational axis for rotating an orientation of substrate 812. It will be appreciated that, in some embodiments, one or more of these example adjustments may be performed programmatically by one or more suitable computer controllers 850. The computer controller 850 may include any of the features described below with respect to controller 850 of FIG. 8.

In some embodiments where plasma may be used as discussed above, showerhead 806 and pedestal 808 electrically communicate with a radio frequency (RF) power supply 814 and matching network 816 for powering a plasma. In some embodiments, the plasma energy may be controlled by controlling one or more of a process station pressure, a gas concentration, an RF source power, an RF source frequency, and a plasma power pulse timing. For example, RF power supply 814 and matching network 816 may be operated at any suitable power to form a plasma having a desired composition of radical species. Likewise, RF power supply 814 may provide RF power of any suitable frequency. In some embodiments, RF power supply 814 may be configured to control high- and low-frequency RF power sources independently of one another. Example low-frequency RF frequencies may include, but are not limited to, frequencies between 0 kHz and 900 kHz. Example high-frequency RF frequencies may include, but are not limited to, frequencies between 1.8 MHz and 2.45 GHz, or greater than about 13.56 MHz, or greater than 27 MHz, or greater than 80 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 850 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., a Mo precursor), instructions for setting a flow rate of a carrier gas (such as argon), and time delay instructions for the first recipe phase. A second, subsequent recipe phase may include instructions for modulating or stopping a flow rate of an inert and/or a reactant gas, and instructions for modulating a flow rate of a carrier or purge gas and time delay instructions for the second recipe phase. A third recipe phase may include instructions for modulating a flow rate of a second reactant gas such as H₂, instructions for modulating the flow rate of a carrier or purge gas, instructions for igniting a plasma, and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. It will be appreciated that these recipe phases may be further subdivided and/or iterated in any suitable way within the scope of the present disclosure.

Further, in some embodiments, pressure control for process station 800 may be provided by butterfly valve 818. As shown in the embodiment of FIG. 8, butterfly valve 818 throttles a vacuum provided by a downstream vacuum pump (not shown). However, in some embodiments, pressure control of process station 800 may also be adjusted by varying a flow rate of one or more gases introduced to the process station 800.

FIG. 9A and FIG. 9B show examples of processing systems. FIG. 9A shows an example of a processing system including multiple chambers. The system 900 includes a transfer module 903. The transfer module 903 provides a clean, vacuum environment to minimize risk of contamination of substrates being processed as they are moved between various modules. Mounted on the transfer module 903 is a multi-station chamber 909 capable of performing in-situ clean and/or ALD processes described above. Initial Mo layer deposition may be performed in the same or different station or chamber as the subsequent Mo gap fill.

Chamber 909 may include multiple stations 911, 913, 915, and 917 that may sequentially perform operations in accordance with disclosed embodiments. For example, chamber 909 may be configured such that station 911 performs an in-situ clean of the substrate using a MoClₓ precursor, as described in FIG. 2 as well as subsequent deposition of the initial Mo layer using the MoClₓ precursor and H₂, and stations 913, 915, and 917 perform ALD of bulk Mo using an molybdenum oxyhalide precursor and H₂. In another example, chamber 909 may be configured such that station 911 performs in-situ clean, station 913 performs ALD of an initial Mo layer, and stations 913 and 914 deposition of bulk Mo. In another example, the chamber 909 may be configured to do parallel processing of substrates, with each station performing multiple processes sequentially.

Two or more stations may be included in a multi-station chamber, e.g., 2-6, with the operations appropriately distributed. For example, a two-station chamber may be configured to perform ALD of an initial Mo layer in a first station followed by ALD of bulk Mo in a second station. Stations may include a heated pedestal or substrate support, one or more gas inlets or showerhead or dispersion plate.

Also mounted on the transfer module 903 may be one or more single or multi-station modules 907. In some embodiments, a preclean as described above may be performed in a module 907, after which the substrate is transferred under vacuum to another module (e.g., another module 907 or chamber 909) for ALD.

The system 900 also includes one or more wafer source modules 901, where wafers are stored before and after processing. An atmospheric robot (not shown) in the atmospheric transfer chamber 919 may first remove wafers from the source modules 901 to loadlocks 921. A wafer transfer device (generally a robot arm unit) in the transfer module 903 moves the wafers from loadlocks 921 to and among the modules mounted on the transfer module 903.

In some embodiments, ALD of Mo is performed in a first chamber, which may be part of a system like system 900, with CVD or PVD of W or Mo or other conductive material deposited as an overburden layer performed in another chamber, which may not be coupled to a common transfer module, but part of another system.

FIG. 9B is an embodiment of a system 900, as described in 9A. The system 900 in FIG. 9B has wafer source modules 901, a transfer module 903, atmospheric transfer chamber 919, and loadlocks 921, as described above with reference to FIG. 9A. The system in Figure B has three single station modules 957. The system 900 may be configured to sequentially perform operations in accordance with disclosed embodiments. For example, the single station modules 957 may be configured so that a first module 957a performs a cleaning operation, a second module 957b performs ALD of an initial Mo layer using a MoClₓ precursor, and a third module 957c performs ALD of bulk Mo using a molybdenum oxyhalide precursor. In this example, an in-situ clean may be optionally performed in second module 957b instead of or in addition to a preclean in first module 957a. Stations may include a heated pedestal or substrate support, one or more gas inlets or showerhead or dispersion plate as described above with reference to FIG. 8.

In various embodiments, a system controller 929 is employed to control process conditions during deposition. The controller 929 will typically include one or more memory devices and one or more processors. A processor may include a CPU or computer, analog and/or digital input/output connections, stepper motor controller boards, etc.

The controller 929 may control all the activities of the apparatus. The system controller 929 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 929 may be employed in some embodiments.

Typically, there will be a user interface associated with the controller 929. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the Mo precursor pulses, hydrogen pulses, and argon flow, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 929. The signals for controlling the process are output on the analog and digital output connections of the deposition apparatus.

The system software may be designed or configured in many ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 929 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 929, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 929, in some implementations, may be a part of or coupled to a computer that is integrated with, coupled to the system, otherwise networked to the system, or a combination thereof. For example, the controller 929 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a PVD chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 929 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

1. A method comprising:
providing a substrate comprising a feature having a feature bottom and feature sidewalls;
depositing an initial molybdenum film in the feature using a molybdenum halide precursor and a reducing agent; and
after depositing the initial molybdenum film, at least partially filling the feature with molybdenum using a molybdenum oxyhalide precursor.

2. The method of claim 1, wherein the feature bottom comprises an oxidized metal silicide surface and the feature sidewalls comprises oxidized metal surfaces, and the method further comprising removing oxide from at least the oxidized metal silicide surface of the feature bottom to leave a metal silicide surface such that the initial molybdenum film is deposited directly on the metal silicide surface.

3. The method of claim 2, wherein the metal silicide surface is one of: titanium silicide (TiSiₓ), nickel silicide (NiSiₓ), molybdenum silicide (MoSiₓ), cobalt silicide (CoSiₓ), platinum silicide (PtSiₓ), ruthenium silicide (RuSiₓ), and nickel platinum silicide (NiPt_{y}Siₓ).

4. The method of claim 2, wherein removing oxide from the oxidized metal silicide surface of the feature bottom comprises a clean with a Cl-based plasma, HF vapor clean, or an ammonium fluoride clean.

5-10. (canceled)

11. The method of claim 1, wherein the molybdenum halide precursor is a molybdenum chloride precursor.

12. The method of claim 1, wherein the molybdenum halide precursor is molybdenum pentachloride (MoCl₅).

13. The method of claim 1, wherein the molybdenum halide precursor is molybdenum hexachloride (MoCl₆).

14-16. (canceled)

17. The method of claim 1, wherein the molybdenum oxyhalide precursor is a molybdenum oxychloride (MoOₓCl_{y}).

18. The method of claim 1, wherein the molybdenum oxyhalide precursor is a molybdenum oxyfluoride (MoOₓF_{y}).

19. (canceled)

20. A method comprising:
providing a substrate comprising a feature having a feature bottom and feature sidewalls, wherein the feature bottom comprises an oxidized surface;
soaking the feature in a molybdenum halide precursor to remove oxide from the oxidized surface to leave an unoxidized surface; and
depositing molybdenum into the feature, including directly on the unoxidized surface, using the molybdenum halide precursor and a reducing agent.

21. (canceled)

22. The method of claim 20, wherein depositing molybdenum into the feature comprises selectively depositing a molybdenum layer on the unoxidized surface relative to the feature sidewalls.

23. The method of claim 22, further comprising, after depositing the molybdenum into the feature depositing a bulk molybdenum layer in the feature using a molybdenum oxyhalide precursor.

24. The method of claim 20, wherein:
the feature bottom comprises a metal-containing surface,
the feature sidewalls comprise a dielectric surface, and
depositing molybdenum further comprises selectively depositing molybdenum on the metal-containing surface relative to the dielectric surface.

25. (canceled)

26. The method of claim 20, wherein the oxidized surface is an oxidized titanium nitride surface.

27. The method of claim 20, wherein soaking the feature in the molybdenum halide precursor is performed in a first chamber and depositing molybdenum into the feature is performed in a second chamber, wherein the first chamber and the second chamber are different chambers.

28. The method claim 20, wherein soaking the feature in the molybdenum halide precursor and depositing the molybdenum into the feature are performed in the same chamber.

29-48. (canceled)

49. A method comprising:
providing a substrate comprising a feature having a feature bottom and feature sidewalls; wherein the feature bottom comprises a metal nitride surface;
depositing an initial molybdenum film on the feature sidewalls and the metal nitride surface of the feature bottom using a molybdenum halide precursor and a reducing agent;
removing molybdenum film from the feature sidewalls, leaving a molybdenum film on the metal nitride surface of the feature bottom; and
at least partially filling the feature with molybdenum.

50. The method of claim 49, wherein the metal nitride is titanium nitride (TiN).

51. (canceled)

52. The method of claim 49, wherein the metal nitride of the feature bottom overlies a stack comprising a semiconductor surface and a titanium silicide (TiSi) layer.

53-54. (canceled)

55. The method of claim 49, further comprising removing at least some metal nitride from the feature sidewalls before depositing an initial molybdenum film on the sidewalls and the metal nitride surface of the feature bottom.
